(19) United States
(12) Patent Application Publication
(10) Pub. No.: US 2012/0212299 A1
(43) Pub. Date: Aug. 23, 2012

(54) METHOD FOR DETERMINING DESIGN VALUES FOR CRYSTAL OSCILLATOR CIRCUIT AND ELECTRONIC APPARATUS

(76) Inventor: Hiroyuki Souma, Chiba-shi (JP)

(21) Appl. No.: 13/370,746

(22) Filed: Feb. 10, 2012

(30) Foreign Application Priority Data
Feb. 21, 2011 (JP) 2011-034845

(51) Int. Cl. H03B 5/36

(52) U.S. Cl. 331/116 FE

(57) ABSTRACT

According to the invention, two of three design values, i.e., the negative resistance RL, load capacitance CL and drive current Ios of a crystal oscillator circuit including a crystal resonator are determined to determine the remaining one design value from a relation equation or relation graph. As a result, reducing the CL of the crystal oscillator circuit allows the drive current Ios to be reduced, achieving reduced power consumption of the crystal oscillator circuit.

### RELATED APPLICATIONS

This application claims priority under 35 U.S.C. §119 to Japanese Patent Application No. 2011-034845 filed on Feb. 21, 2011, the entire content of which is hereby incorporated by reference.

### BACKGROUND OF THE INVENTION

1. Field of the Invention

The present invention is to provide a crystal oscillator circuit with low power consumption, and particularly relates to a method for determining design values including the load capacitance, negative resistance and drive current for a crystal oscillator circuit, and an electronic apparatus including an oscillator circuit the design values for which are determined using the method.

2. Description of the Related Art

For a portable apparatus, such as a watch or mobile phone, long time operation without charging and reduction in frequency of charging a built-in battery are desired. Accordingly, there is a growing demand for reducing drive power of an oscillator circuit including a piezoelectric device, such as a crystal resonator, used for the portable apparatus and significantly reducing power consumption of the oscillator circuit in standby mode (i.e., when the oscillator circuit is oscillating in unloaded condition).

FIG. 9 shows a typical oscillator circuit including a crystal resonator, including: a CMOS inverter IV01 as an inverting amplifier; a crystal resonator X2 connected between the input terminal XCIN and output terminal XCOUT of the CMOS inverter IV01; a capacitor providing a load capacitance Cg connected between the input terminal XCIN of the CMOS inverter IV01 and the power supply terminal Vss of a ground potential; and a capacitor providing a load capacitance Cd connected between the output terminal XCOUT of the CMOS inverter IV01 and the power supply terminal Vss of the ground potential.

The CMOS inverter IV01 includes a PMOS transistor PM11 and an NMOS transistor NM11 connected in series between a first power supply terminal and a second power supply terminal supplied with a power supply voltage Vdd and the ground potential, respectively, and a feedback resistor Rf. Drive current adjusting resistors r1 and r2 limit drive current for exciting the crystal resonator X2, the resistor r1 being connected between the source of the PMOS transistor PM11 of the CMOS inverter IV01 and the first power supply terminal, the resistor r2 being connected between the NMOS transistor NM11 of the CMOS inverter IV01 and the second power supply terminal.

In recent years, there is a demand for reducing power consumption of an oscillator circuit included in a portable apparatus or the like. In order to meet this demand, drive current of a crystal resonator of the oscillator circuit needs to be reduced. In order to do this, reducing the transconductance Gm of a CMOS inverter of the oscillator circuit would be appropriate, but reducing the transconductance Gm may reduce the oscillation margin of the oscillator circuit.

The oscillation margin M of the oscillator circuit is given by the following equation (1):

M={|−Gm|/(ω²Cg·Cd)}*(1/R1(max))=+RL/R1(max) Eq. (1)

where ω is angular frequency of oscillation frequency, RL is negative resistance, R1(max) is the maximum value of the effective resistance R1 of the crystal resonator, and the oscillation margin M needs to be 5 or more.

Since the effective resistance R1 of the crystal resonator is to be determined in order to downsize the crystal resonator, the effective resistance R1 cannot be reduced too much. So, in order to maintain the oscillation margin M of the oscillator circuit while reducing the transconductance Gm, the load capacitances Cg and/or Cd of the capacitors providing the external load capacitance of the CMOS inverter should be reduced. So, in order to achieve this, the crystal resonator of the oscillator circuit needs to have a load capacitance CL meeting the requirement of reducing power consumption of a built-in IC, such as a microcomputer. In view of this, the applicant has already proposed the reduction of the load capacitance CL, or reduced CL (3-5 pF) with respect to the load capacitance CL of 12.5 pF for a conventional crystal resonator (JP-A-2008-205658).

However, reducing the load capacitance CL makes noticeable a problem of the capacitance tolerance of load capacitance CL and the frequency deviation Δf of oscillation frequency. For example, the oscillation frequency stability Δf (in ppm) when the load capacitance CL varies by ΔC (±5%) which is within a normal capacitance tolerance is 7.3 ppm with a load capacitance CL of 12.5 pF and ΔC of 1.25 pF; 13.2 ppm with a load capacitance CL of 6 pF and ΔC of 0.6 pF; and 20.5 ppm with a load capacitance CL of 3 pF and ΔC of 0.3 pF. This means that the load capacitance CL of 3 pF exhibits 2.8 times as much frequency deviation as the conventional load capacitance CL of 12.5 pF. So, in order to reduce the load capacitance CL (achieve reduced CL), the oscillation frequency stability with respect to the capacitance tolerance of the load capacitance CL needs to be improved.

FIG. 10 shows an equivalent circuit of the circuit in FIG. 9 between the input/output terminals XCIN and XCOUT on the crystal resonator side. The crystal resonator X2 and the load capacitance CL are connected in series. The crystal resonator is expressed as a circuit in which a serial resonance circuit of an inductance L1, a capacitance C1 and a resistance R1 that equivalently represents a mechanical resonance due to a piezoelectric effect and an inter-electrode capacitance C0 are connected in parallel. Also, various stray capacitances due to a CMOS semiconductor substrate, signal wires and the like exist between the input/output terminals XCIN and XCOUT. Referring to a combined stray capacitance of these stray capacitances as Cs, the load capacitance CL is a parallel connection of the stray capacitance Cs and the external capacitances Cg and Cd connected in series as shown in FIG. 11.

Accordingly,

CL=Cs+Cg*Cd/(Cg+Cd) Eq. (2).

Selecting external capacitors Cg and Cd matching with the oscillation frequency so that the CL will be 2-6 pF that meets the relation of (2) can improve the oscillation frequency stability. Specifically, since the load capacitance CL is the sum of the stray capacitance Cs and the external capacitance Cext {=Cg*Cd/(Cg+Cd)}, selecting the value of the external capacitance Cext to be corresponding to the difference between the load capacitance CL and the stray capacitance Cs may satisfy the equation (2), causing the load capacitance CL of the crystal resonator to match with the load capacitance on the oscillator circuit side with respect to the crystal resonator.

As described above, employing a low load capacitance CL may achieve a low transconductance Gm while maintaining oscillation frequency stability. However, a problem with employing a crystal oscillator circuit in which a crystal resonator having the low load capacitance CL is used is that it is not obvious how much drive current can be obtained. Currently, the relation between the low load capacitance CL and the drive current has not been clarified. However, the capability of preestimating the drive current of the crystal oscillator circuit highly facilitates designing the IC. Or, when a target value of the drive current of the crystal oscillator circuit is appropriately set as part of specification of the IC, it is very important to know whether a crystal resonator that can achieve that drive current value exists or not. Thus, there is a strong demand for knowing the relation between the drive current Ios and load capacitance CL of the crystal oscillator circuit.

### SUMMARY OF THE INVENTION

It is an object of the present invention to clarify the relation between the drive current Ios and load capacitance CL of an oscillator circuit including a crystal resonator and provide a method for determining how much load capacitance CL is to be used for obtaining a desired drive current Ios. It is also an object of the invention to clarify how the negative resistance RL affects the drive current Ios and load capacitance CL. In other words, it is an object of the invention to clarify the relation between the load capacitance CL, negative resistance RL and drive current Ios of an oscillator circuit including a crystal resonator and provide a method for determining design values for the crystal oscillator circuit. It is also an object of the invention to provide an electronic apparatus including a crystal oscillator circuit the design values for which are determined using the above method.

Specifically, the invention is implemented as follows:

(1) The invention provides a method for determining design values for an oscillator circuit in which two of three design values, i.e., the negative resistance RL, load capacitance CL and drive current Ios of a crystal oscillator circuit including a crystal resonator are determined to determine the remaining one design value from a relation equation or relation graph.

(2) The invention provides the method for determining design values for an oscillator circuit in which, with the negative resistance RL set to a constant value, a relation equation between the drive current Ios and the load capacitance CL is expressed by a quadratic relation Ios=α*(CL)²+β*(CL)+γ(α, β, and γ are constants), then the drive current Ios is determined from the load capacitance CL using the relation equation, or the load capacitance CL is determined from the drive current Ios using the relation equation.

(3) The invention provides the method for determining design values for an oscillator circuit in which relation equations between the drive current Ios and the load capacitance CL with at least two negative resistances RL (RL1 and RL2) previously obtained are given by:

Ios=c1*(CL)²+d1*(CL)+e1(RL=RL1) and

Ios=c2*(CL)²+d2*(CL)+e2(RL=RL2),

then, using the above equations, a relation equation between the drive current Ios and the load capacitance CL with a negative resistance RL0 is determined as follows:

Ios=c0*(CL)²+d0*(CL)+e0(RL=RL0).

(4) The invention provides the method for determining design values for an oscillator circuit in which, if RL1<RL0<RL2, the equations

Ios=c1*(CL)²+d1*(CL)+e1(RL=RL1) and

Ios=c2*(CL)²+d2*(CL)+e2(RL=RL2)

are used to determine on a simple pro-rata basis a relation equation between the drive current Ios and the load capacitance CL with the negative resistance RL0 as follows:

Ios=c0*(CL)²+d0*(CL)+e0(RL=RL0).

(5) The invention provides the method for determining design values for an oscillator circuit in which, with the drive current Ios set to a parameter or constant value, a relation equation between the load capacitance CL and the negative resistance RL is expressed by a power equation CL=a*(RL)^{b} (a and b are constants), then the load capacitance CL is determined from the negative resistance RL using the relation equation, or the negative resistance RL is determined from the load capacitance CL using the relation equation.

(6) The invention provides the method for determining design values for an oscillator circuit in which relation equations between the negative resistance RL and the load capacitance CL with at least two drive currents Ios (Ios1 and Ios2) previously obtained are given by:

CL=a1*(RL)^{b1}(Ios=Ios1) and

CL=a2*(RL)^{b2}(Ios=Ios2),

then, using these equations, a relation equation between the negative resistance RL and the load capacitance CL with a drive current Ios0 is determined as follows:

CL=a0*(RL)^{b0}(Ios=Ios0).

(7) The invention provides the method for determining design values for an oscillator circuit in which, if Ios1<Ios0<Ios2, the equations

CL=a1*(RL)^{b1}(Ios=Ios1) and

CL=a2*(RL)^{b2}(Ios=Ios2)

are used to determine on a simple pro-rata basis a relation equation between the negative resistance RL and the load capacitance CL with a drive current Ios0 as follows:

CL=a0*(RL)^{b0}(Ios=Ios0).

(8) The invention provides the method for determining design values for an oscillator circuit in which the negative resistance RL is determined from an oscillation margin M, M being expressed by M=RL/R1(max), R1(max) being the maximum value of an effective resistance R1 of the crystal resonator.

According to the invention, it is clarified that a certain relation exists between the load capacitance CL and negative resistance RL which are important parameters for an oscillator circuit and the drive current Ios that flows in the oscillator circuit. Using this relation, design values of the parameters can be determined. This is particularly important when designing an oscillator circuit with low power consumption. For example, with a target value Ios0 of the drive current Ios set, the load capacitance CL is expressed by a power equation of the negative resistance RL CL=a*(RL)^{b}, so a load capacitance CL0 for an appropriate negative resistance RL0 can be determined. Or if a load capacitance CL0 is selected, a corresponding negative resistance RL0 can be determined. Furthermore, with the negative resistance RL set as a parameter, the drive current Ios is expressed by a quadratic equation of the load capacitance CL Ios=a*(CL)²+β*(CL)+γ. So, if an appropriate load capacitance CL0 is selected, a corresponding drive current Ios0 that flows in the oscillator circuit can be determined. Or a load capacitance CL0 can be determined for a target value Ios0 of the drive current Ios. Previously, for an oscillator circuit with a low CL (less than or equal to 8 pF), how much drive current Ios can be achieved and how much negative resistance RL is needed with the low CL have not been clarified. The invention clarifies the relation of them, highly facilitating designing an oscillator circuit. Also, reducing the CL of the crystal oscillator circuit allows the drive current Ios to be highly reduced, achieving reduced power consumption of the crystal oscillator circuit. As a result, an electronic apparatus including the crystal oscillator circuit can also achieve reduced power consumption.

### BRIEF DESCRIPTION OF THE DRAWINGS

FIG. 1 shows a measurement circuit that was used for clarifying the relation between the drive current Ios, the load capacitance CL and the negative resistance RL;

FIGS. 2A and 2B are graphs showing the relation between the load capacitance CL and the negative resistance RL with the drive current Ios set as a parameter (i.e., held constant);

FIGS. 3A and 3B are graphs showing the relation between the load capacitance CL and the negative resistance RL with the drive current Ios set as a parameter (i.e., held constant);

FIGS. 4A-4D are graphs showing the relation between the drive current Ios and the load capacitance CL with the negative resistance RL set as a parameter (i.e., held constant);

FIGS. 5A-5F are graphs showing the relation between the drive current Ios and the load capacitance CL with the negative resistance RL set as a parameter (i.e., held constant);

FIG. 6 is a graph showing the relation between the drive current Ios and the load capacitance CL with the negative resistance RL set as a parameter (i.e., held constant);

FIG. 7 is a graph showing the relation between the drive current Ios and the load capacitance CL with the negative resistance RL set as a parameter (i.e., held constant);

FIG. 8 is a graph showing the relation between the load capacitance CL and the negative resistance RL with the drive current Ios set as a parameter (i.e., held constant);

FIG. 9 shows an oscillator circuit including a crystal resonator;

FIG. 10 shows an equivalent circuit of the circuit in FIG. 9 between the input/output terminals XCIN and XCOUT on the crystal resonator side; and

FIG. 11 shows capacitances included in the load capacitance CL.

### DETAILED DESCRIPTION OF THE PREFERRED EMBODIMENTS

It is an object of the present invention to clarify the relation between the drive current Ios, load capacitance CL and negative resistance RL of a crystal oscillator circuit including a crystal resonator and provide a method for determining how much load capacitance CL and negative resistance RL are to be used for obtaining a desired drive current Ios. It is also an object of the invention to provide a method for determining how much load capacitance CL is to be used for reducing the drive current Ios and estimating how much negative resistance RL would be for the determined load capacitance CL. In other words, the invention provides a method for determining design values for a crystal oscillator circuit in which any two of three design values, i.e., the negative resistance RL, load capacitance CL and drive current Ios of an oscillator circuit including a crystal resonator are determined to determine the remaining one design value from a relation equation or relation graph. The invention also provides an electronic apparatus including a crystal oscillator circuit the design values for which are determined using the above method.

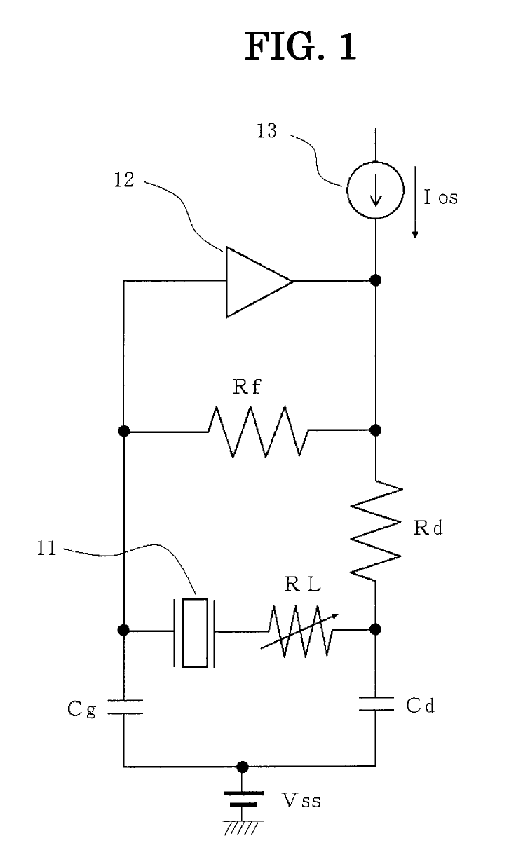

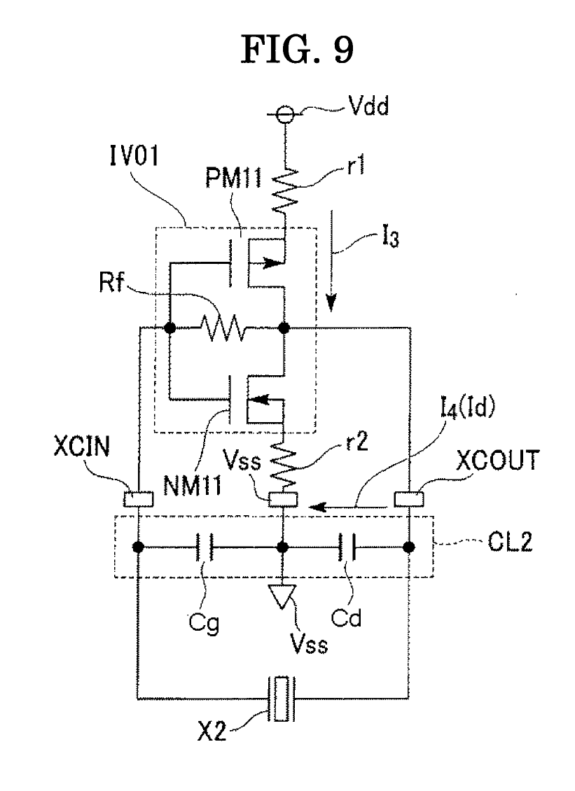

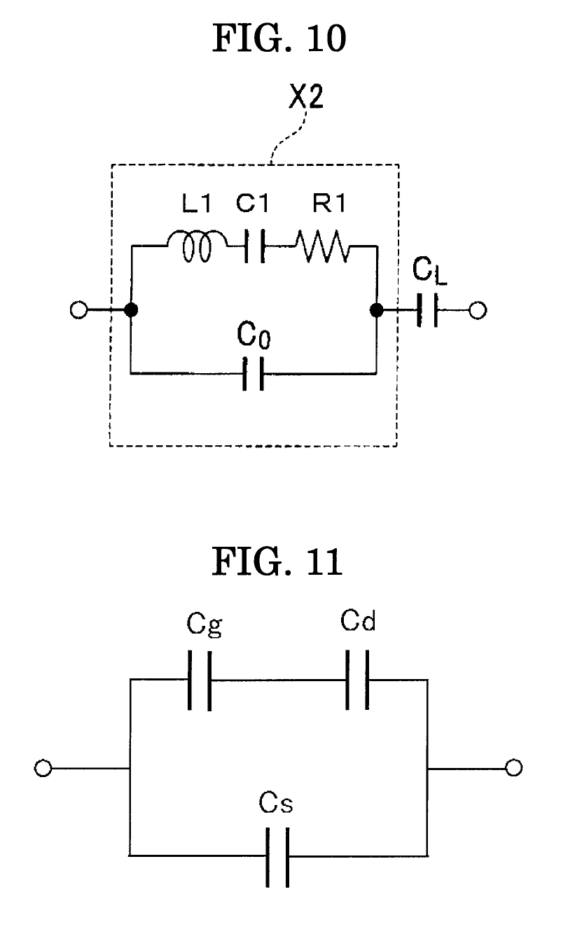

FIG. 1 shows a measurement circuit that was used for clarifying the relation between the drive current Ios, load capacitance CL and negative resistance RL of a crystal oscillator circuit using a crystal resonator. FIG. 1 is essentially similar to FIG. 9. A crystal resonator SSP-T7-FL (fundamental frequency: 32.768 kHz) from SII was used as a crystal resonator 11. The measurement circuit included a CMOS inverter 12 and a constant current source 13 and was configured to allow constant current (i.e., the drive current Ios) to flow in the crystal oscillator circuit. Using the measurement circuit, the load capacitance CL and the negative resistance RL were measured for various capacitances Cg and Cd. Additionally, a feedback resistor Rf of 10 MΩ was used.

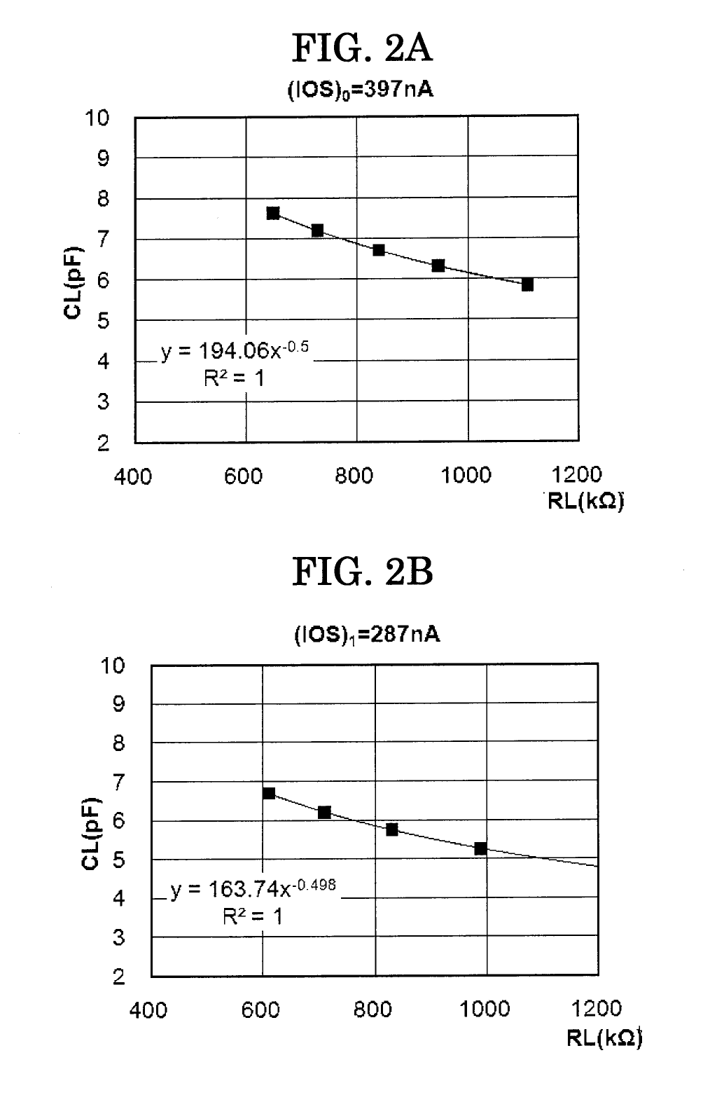

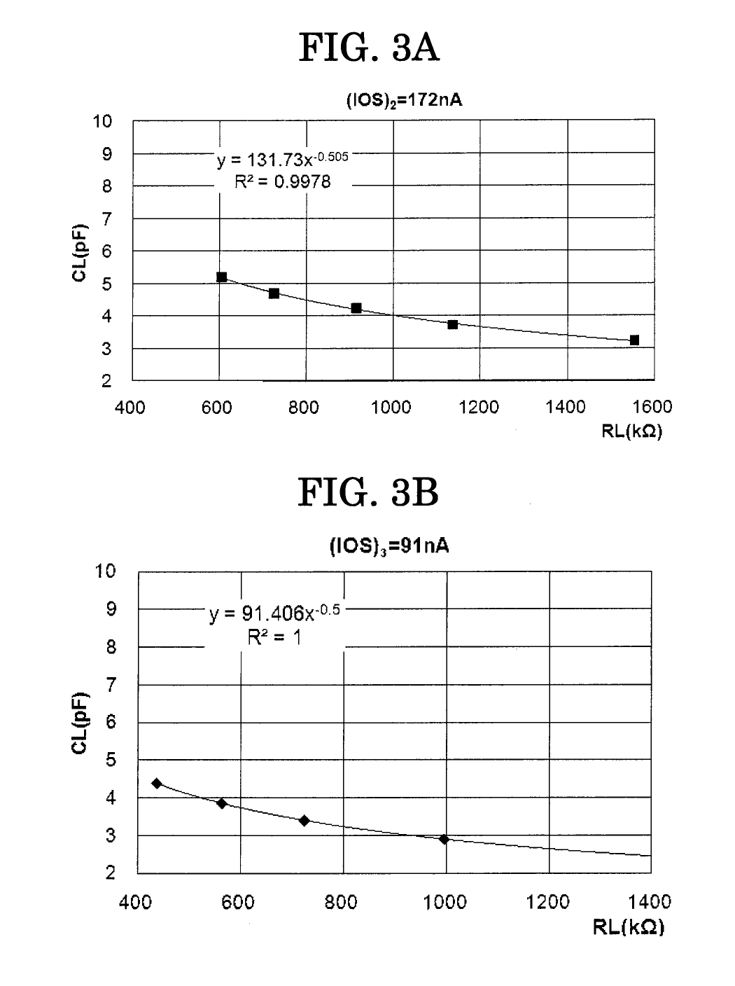

FIGS. 2 and 3 are graphs showing the relation between the load capacitance CL and the negative resistance RL with the drive current Ios set as a parameter (i.e., held constant). FIG. 2A is a graph with Ios=397 nA; FIG. 2B is a graph with Ios=287 nA; FIG. 3A is a graph with Ios=172 nA; and FIG. 3B is a graph with Ios=91 nA. All of these four graphs indicate a power relation expressed by y=a*x^{b}+c (a, b, and c are constants; y and x correspond to CL and RL, respectively). Then, the constants were determined from an power approximate equation as follows: FIG. 2A indicates y=194.06x^{-0.55} (correlation coefficient R=1) with Ios=397 nA; FIG. 2B indicates y=163.74x⁻⁴⁹⁸⁵ (correlation coefficient R=1) with Ios=287 nA; FIG. 3A indicates y=131.73x^{-0.5054} (correlation coefficient R=0.999) with Ios=172 nA; and FIG. 3B indicates y=91.406x^{-0.5} (correlation coefficient R=0.1) with Ios=91 nA. Thus, the correlation coefficients are extremely high, then b and c may be considered to be −0.5 and 0, respectively. This resulted relation equation CL=a*(RL)^{-0.5}, predicted from RL=|−Gm|/(ω²Cg·Cd) of the above described Eq. (1), is a very reasonable relation equation (approximate equation). In this way, the crystal oscillator circuit with reduced CL can operate even with very low consumption current to achieve reduced power consumption.

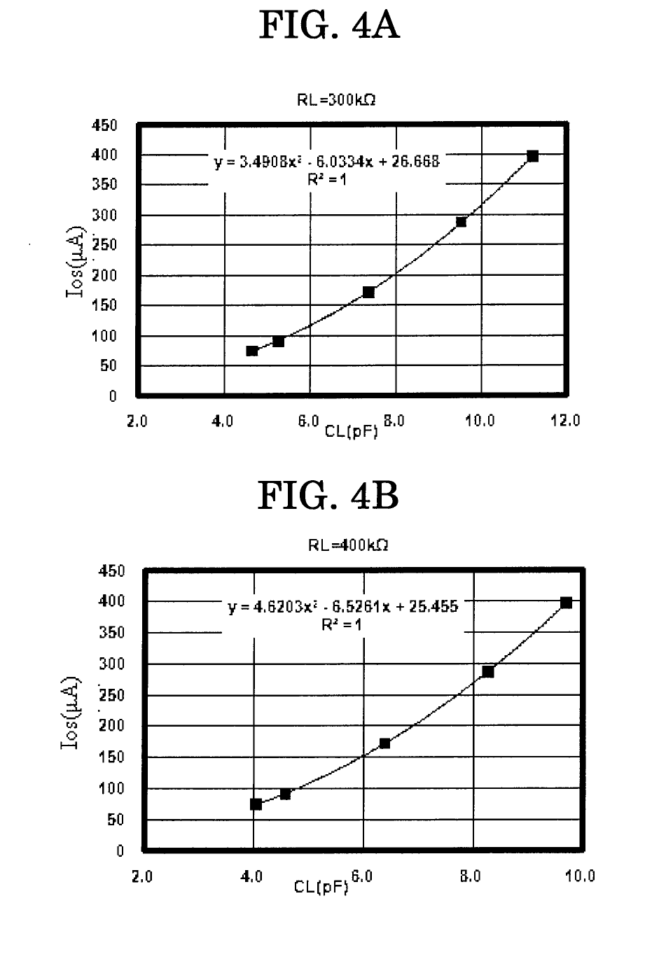

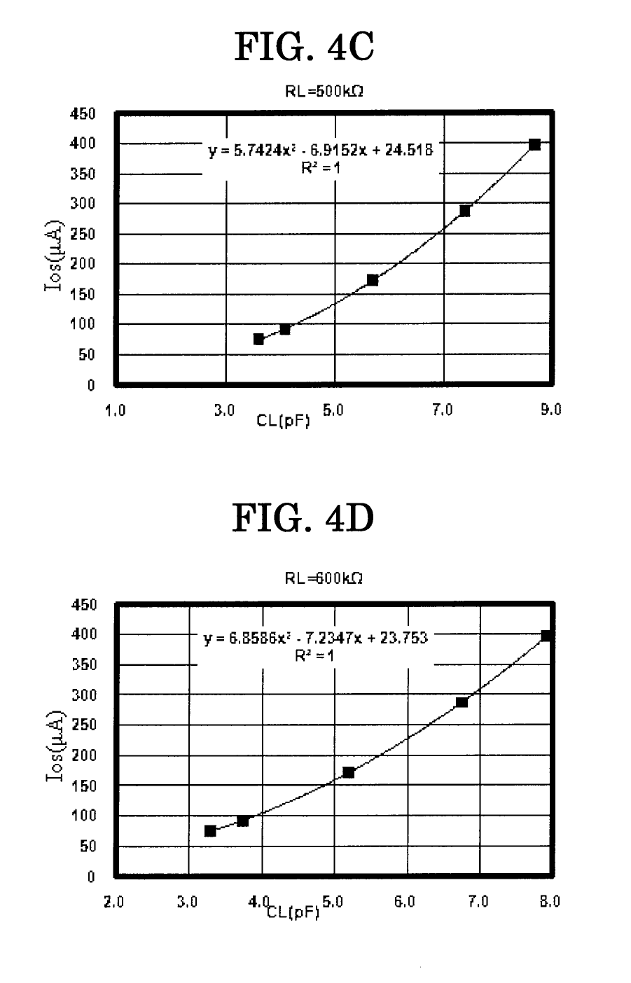

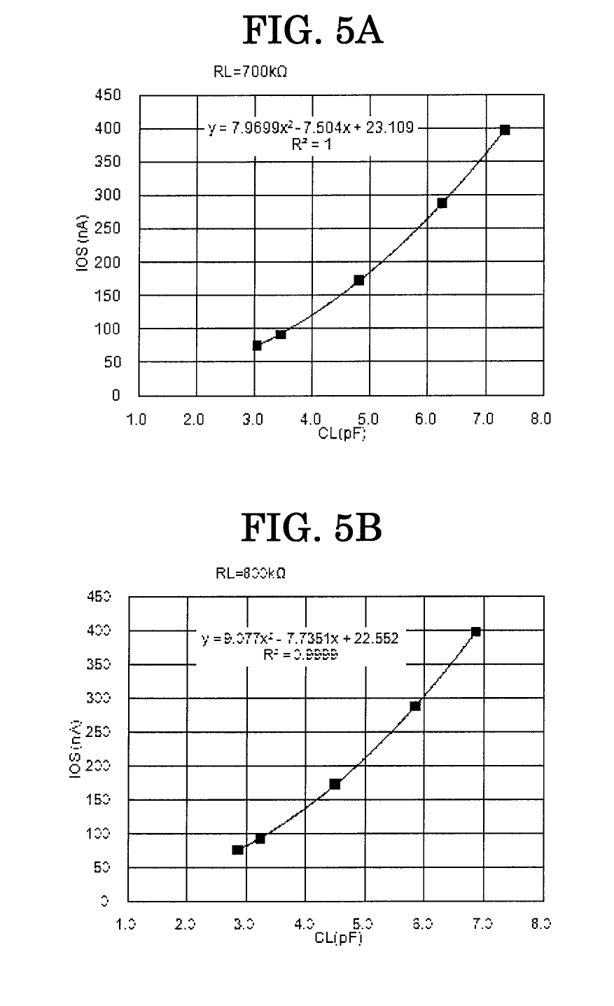

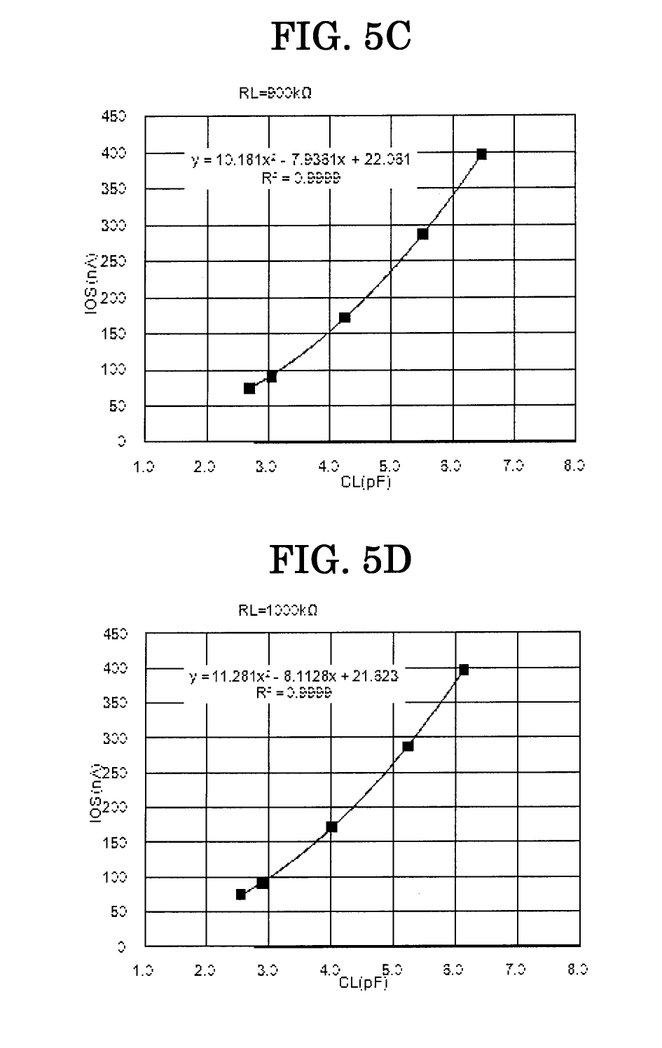

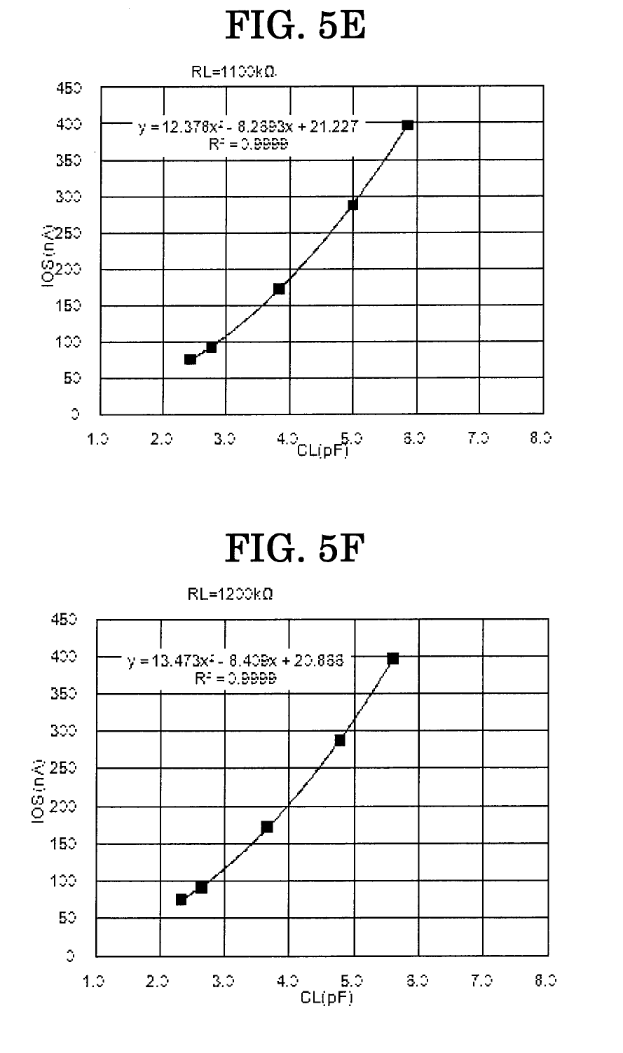

FIGS. 4 and 5 are graphs showing the relation between the drive current Ios and the load capacitance CL with the negative resistance RL set as a parameter (i.e., held constant). These graphs were obtained from the relation equations using the data shown in FIGS. 2 and 3. FIGS. 4A-4D are graphs with negative resistances RL of 300, 400, 500 and 600 kΩ, respectively. FIGS. 5A-5F are graphs with negative resistances RL of 700, 800, 900, 1000, 1100 and 1200 kΩ, respectively. All of these ten graphs indicate a quadratic relation expressed by y=a*x²+β*x+γ (α, β, and γ are constants; y and x correspond to Ios and CL, respectively). The relation equations of the drive current Ios and load capacitance CL with the various negative resistances RL are shown in the respective graphs. With very high correlation coefficients, the drive current Ios may be considered to be proportional to the square of the load capacitance CL. This can be predicted from the fact that, in RL=|−Gm|/(ω²Cg·Cd) derived from Eq. (1), the transconductance Gm is proportional to CL² with Cg=Cd=2CL. In this way, reducing CL can make the drive current Ios very low.

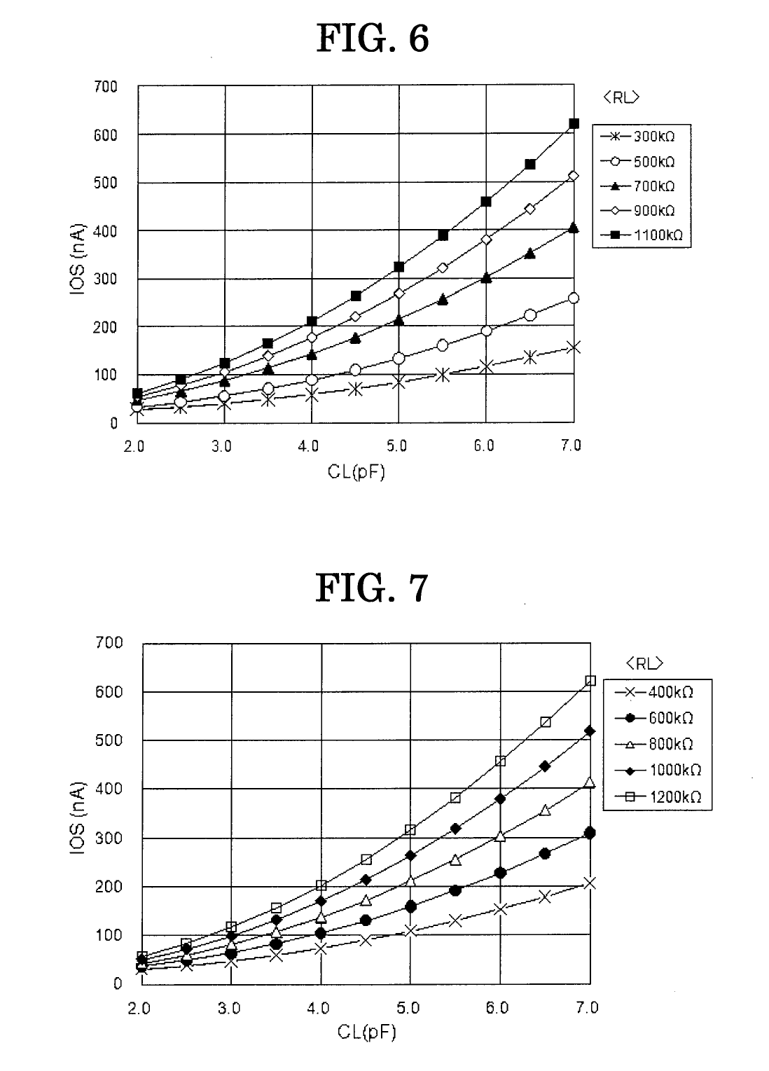

These graphs are superimposed on one another as shown in FIGS. 6 and 7. FIG. 6 shows the characteristics with the negative resistances RL of 300-1100 kΩ in 200 kΩ steps. FIG. 7 shows the characteristics with the negative resistances RL of 400-1200 kΩ in 200 kΩ steps. As seen from these graphs, with the same negative resistance RL, the drive current Ios continuously decreases as the negative resistance RL increases. Thus, when a negative resistance RL0 is selected, corresponding relation between the drive current Ios and the load capacitance CL can be determined. For example, if the negative resistance RL0 takes some value between 800 kΩ and 900 kΩ, a drive current Ios1 with a load capacitance CL0 is determined from the relation equation y=9.077x²−7.504x+23.109 with RL=800 kΩ, then a drive current Ios2 with the load capacitance CL0 is determined from the relation equation y=10.181x²−7.9361x+22.061 with RL=900 kΩ, and then an Iso0 with the negative resistance RL0 and the load capacitance CL0 can be determined on a simple pro-rata basis between the drive currents Ios1 and Ios2. Also, by determining drive currents Ios for various load capacitances CL and plotting them to adapt a quadratic equation thereto, a relation equation (quadratic equation) between the drive current Ios and the load capacitance CL with the negative resistance RL0 can also be obtained. Similarly, for any negative resistance RL in the range of 300-1200 kΩ, a drive current Ios for a certain load capacitance CL can be determined, and also, a relation equation (quadratic equation) between the drive current Ios and the load capacitance CL can be obtained. Similarly, with a negative resistance RL less than or equal to 300 kΩ or more than or equal to 1200 kΩ, using an external ratio, a drive current Ios for a certain load capacitance CL can be determined, and also, a relation equation (quadratic equation) between the drive current Ios and the load capacitance CL can be obtained.

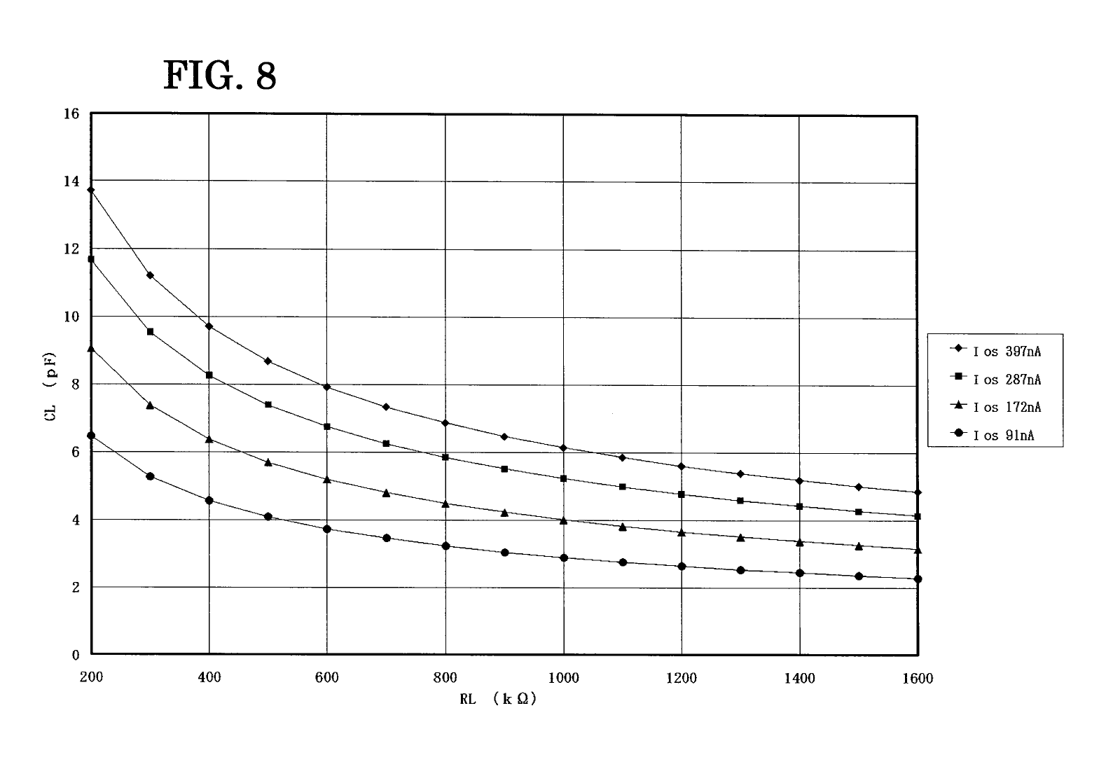

FIG. 8 is a combined graph of the relations between the load capacitance CL and the negative resistance RL shown in FIGS. 2 and 3. This graph includes data calculated using the approximate equation. As seen from this graph, it is expected that, for a given negative resistance RL, the drive current Ios continuously increases as the load capacitance CL increases. From this graph and the relation equations, a relation between the load capacitance CL and the negative resistance RL with a constant drive current Ios can be derived. Specifically, by using two relation curves CL=a1*(RL)^{b1} (Ios=Ios1) and CL=a2*(RL)^{b2} (Ios=Ios2) with known relation equations to determine a load capacitance CL for a given negative resistance RL on a simple pro-rata basis, a relation curve CL=a0*(RL)^{b0} (Ios=Ios0) between the negative resistance RL and the load capacitance CL with a constant drive current Ios0 can be determined. If Ios1<Ios0<Ios2, the relation curve CL=a0*(RL)^{b0} (Ios=Ios0) may be determined by determining a load capacitance CL for a given negative resistance RL on a simple pro-rata basis and plotting the load capacitance CL. For example, if 172 nA<Ios0<287 nA, a desired relation equation can be obtained by using y=131.73x^{-0.5054} and y=163.74x^{-0.4985} to determine a load capacitance CL for a given RL (200 kΩ<RL<1600 kΩ), plot the load capacitance CL and adapt an approximate equation. As seen from these results, if the load capacitance CL<8 pF, the drive current Ios<400 nA can be achieved with the negative resistance RL of 200 kΩ<RL<1600 kΩ (or more than or equal to 1600 kΩ), preferably 400 kΩ<RL<1600 kΩ (or more than or equal to 1600 kΩ), and more preferably 600 kΩ<RL<1600 kΩ (or more than or equal to 1600 kΩ).

Next, a method for determining various design values from the oscillation margin M of the above-described Eq. (1) is described. Once a value of the oscillation margin M is set (here, the M is set to M0), a negative resistance RL0 can be determined from Eq. (1) (RL0=M0*R1(max)). In order to ensure stable oscillation, the M generally needs to be 5 or more. If the RL0 is between 200 and 1600, a quadratic equation Ios=a0*(CL)²+β0*(CL)+γ0 (α0, β0 and γ0 are constants) is determined using the above-described method. Using this relation equation, target values, i.e., a drive current Ios0 and a load capacitance CL0 can be determined. If the RL0 is not between 200 and 1600, a predicted quadratic equation Ios=a0*(CL)²+β0*(CL)+γ0 may be determined by the above-described method using an external ratio. Or, various drive currents Ios and load capacitances CL with the negative resistance RL outside the range may be determined to obtain a new relation equation based on actual measured values. When a conventional high load capacitance (CL>10 pF, e.g., 12.5 pF) was used, reducing power consumption was difficult because the drive current Ios was increased to increase the oscillation margin M, increasing the Gm. However, the technique for reducing the CL the applicant has been investigating allows reducing the load capacitance CL to reduce the drive current Ios while maintaining the oscillation margin M (i.e., adjusting the negative resistance RL).

As has been described, the invention was found from the fact that the three design values, i.e., the negative resistance, the load capacitance and the drive current are highly correlated with one another. The invention allows designing and providing an oscillator circuit having very low drive current Ios while maintaining oscillation margin M even when reducing CL. Also, the oscillator circuit of the invention can be included and used in any oscillator circuit used for an oscillator or electronic apparatus including a crystal resonator or another piezoelectric resonator. For example, the electronic apparatus may be a battery-driven electronic apparatus, such as a watch, mobile phone, personal digital assistant, notebook computer and the like. Furthermore, the invention is applicable to a wide range of electronic apparatuses, including in-car electronic apparatuses required for energy saving or power saving and home-use products, such as a television-set, refrigerator and air-conditioner.

The invention can be used for a crystal oscillator circuit including a crystal resonator. Particularly, the invention is useful in designing an oscillator circuit with low power consumption. Also, the invention can be used for an oscillator or electronic apparatus including an oscillator circuit including a piezoelectric resonator.

What is claimed is:

1. A method for determining design values for a crystal oscillator circuit, wherein two of three design values, i.e., the negative resistance RL, load capacitance CL and drive current Ios of a crystal oscillator circuit including a crystal resonator are determined to determine the remaining one design value from a relation equation or relation graph.

2. The method for determining design values for a crystal oscillator circuit according to claim 1, wherein, with the negative resistance RL set to a constant value, a relation equation between the drive current Ios and the load capacitance CL is expressed by a quadratic relation Ios=a*(CL)²+β*(CL)+γ (α, β, and γ are constants), then the drive current Ios is determined from the load capacitance CL using the relation equation, or the load capacitance CL is determined from the drive current Ios using the relation equation.

3. The method for determining design values for a crystal oscillator circuit according to claim 2, wherein relation equations between the drive current Ios and the load capacitance CL with at least two negative resistances RL (RL1 and RL2) previously obtained are given by:
Ios=c1*(CL)²+d1*(CL)+e1(RL=RL1) and
Ios=c2*(CL)²+d2*(CL)+e2(RL=RL2),
then, using these equations,
a relation equation between the drive current Ios and the load capacitance CL with a negative resistance RL0 is determined as follows:
Ios=c0*(CL)²+d0*(CL)+e0(RL=RL0).

4. The method for determining design values for a crystal oscillator circuit according to claim 3, wherein, if RL1<RL0<RL2, the equations
Ios=c1*(CL)²+d1*(CL)+e1(RL=RL1) and
Ios=c2*(CL)²+d2*(CL)+e2(RL=RL2)
are used to determine on a simple pro-rata basis a relation equation between the drive current Ios and the load capacitance CL with the negative resistance RL0 as follows:
Ios=c0*(CL)²+d0*(CL)+e0(RL=RL0).

5. The method for determining design values for a crystal oscillator circuit according to claim 1, wherein, with the drive current Ios set to a constant value, a relation equation between the load capacitance CL and the negative resistance RL is expressed by CL=a*(RL)^{b} (a and b are constants), then the load capacitance CL is determined from the negative resistance RL using the relation equation, or the negative resistance RL is determined from the load capacitance CL using the relation equation.

6. The method for determining design values for a crystal oscillator circuit according to claim 5, wherein relation equations between the negative resistance RL and the load capacitance CL with at least two drive currents Ios (Ios1 and Ios2) previously obtained are given by:
CL=a1*(RL)^{b1}(Ios=Ios1) and
CL=a2*(RL)^{b2}(Ios=Ios2),
then, using these equations,
a relation equation between the negative resistance RL and the load capacitance CL with a drive current Ios0 is determined as follows:
CL=a0*(RL)^{b0}(Ios=Ios0).

7. The method for determining design values for a crystal oscillator circuit according to claim 6, wherein b=b1=b2=b0=−0.5.

8. The method for determining design values for a crystal oscillator circuit according to claim 7, wherein, if Ios1<Ios0<Ios2, the equations
CL=a1*(RL)^{b1}(Ios=Ios1) and
CL=a2*(RL)^{b2}(Ios=Ios2)
are used to determine a relation equation between the negative resistance RL and the load capacitance CL with a drive current Ios0 as follows:
CL=a0*(RL)^{b0}(Ios=Ios0).

9. An electronic apparatus comprising a crystal oscillator circuit the design values for which are determined using the method for determining design values for a crystal oscillator circuit according to claim 1.
